(19) United States
(12) Patent Application Publication
(10) Pub. No.: US 2015/0069556 A1
(43) Pub. Date: Mar. 12, 2015

(54) MAGNETIC MEMORY AND METHOD FOR MANUFACTURING THE SAME

(71) Applicant: KABUSHIKI KAISHA TOSHIBA, Tokyo (JP)

(72) Inventors: Koji YAMAKAWA, Yokkaichi-shi (JP); Sachiyo ITO, Yokohama-shi (JP); Masahiko HASUNUMA, Yokkaichi-shi (JP); Kenji NOMA, Yokohama-shi (JP); Hiroyuki YANO, Yokkaichi-shi (JP)

(21) Appl. No.: 14/202,622

(22) Filed: Mar. 10, 2014

Related U.S. Application Data
(60) Provisional application No. 61/876,512, filed on Sep. 11, 2013.

(51) Int. Cl. H01L 43/02; H01L 43/12

(52) U.S. Cl. CPC H01L 43/02; H01L 43/12
USPC 257/421; 438/3

(57) ABSTRACT

According to one embodiment, a magnetic memory is disclosed. The magnetic memory includes a substrate, a first magnetoresistive element provided on the substrate. A second magnetoresistive element which is provided on the substrate and is arranged next to the first magnetoresistive element. Each of the first and second magnetoresistive elements includes a first magnetic layer, a tunnel barrier layer and a second magnetic layer. The tunnel barrier layer is provided on the first magnetic layer, the second magnetic layer is provided on the tunnel barrier layer. A first stress member having a tensile stress as an internal stress is provided on an area including a side face of the stacked body.

### CROSS-REFERENCE TO RELATED APPLICATIONS

This application claims the benefit of U.S. Provisional Application No. 61/876,512, filed Sep. 11, 2013, the entire contents of which are incorporated herein by reference.

### FIELD

Embodiments described herein relate generally to a magnetic memory including a magnetoresistive element and a method for manufacturing the same.

### BACKGROUND

Recently, as a nonvolatile semiconductor memory (semiconductor memory), a magnetic random access memory (hereinafter, referred to as MRAM) using the tunneling magnetoresistive effect (TMR) has been developed. The MRAM is a nonvolatile semiconductor memory having a feature of performing high-speed reading/writing, operating in low power consumption, and being able to grow in capacity, and is expected to be applied as a working memory. The MRAM has a magnetic tunnel junction (hereinafter, referred to as MTJ) element, and the MTJ element is a magnetoresistive effect element having a large magnetoresistive change ratio.

In detail, a structure of this MTJ element is basically a stacked structure having three layers of a storage layer including a magnetization film for memorizing data by changing the direction of magnetization, a reference layer including a magnetization film which is used by fixing the magnetization in one direction, and a tunnel barrier layer (nonmagnetic layer) including an insulating film formed between these layers.

When an electric current is supplied to the MTJ element including the storage layer/the tunnel barrier layer/the reference layer, the resistance of the MTJ element changes in accordance with a direction of magnetization of the storage layer with respect to a direction of magnetization the reference layer; more specifically, a minimum value is taken if the directions of magnetization of the storage layer and the reference layer are parallel to each other, and a maximum value is taken if the directions are antiparallel to each other.

This phenomenon is called a tunneling magneto-resistance effect (hereinafter, referred to as TMR effect), and a parallel state and an antiparallel state of magnetization of the storage layer and the reference layer are used as “0” and “1” of data, respectively, for memory operations.

Conventionally, to operate the MRAM, the direction of magnetization of the storage layer has been reversed by using a magnetic field which is generated by supplying the current to wiring arranged in proximity of the storage layer of the MTJ element (magnetic field write method).

However, in such a magnetic field write method, although a generated magnetic field can be made large by increasing a current value, it has been difficult to realize a large-capacity memory of the MRAM because as miniaturization of the MRAM is advanced the current value allowed for the wiring becomes limited.

Incidentally, the write current necessary for writing can be reduced by bringing the wiring closer to the storage layer, or devising a material constituting the wiring, etc, but, there is a problem that the coercivity of the storage layer also becomes large in principle due to the miniaturization of the MTJ element. That is, in the magnetic field write method, it is extremely difficult to perform both of miniaturization of the MTJ element or the like, and reduction of the write current at the same time.

Thus, recently, a spin injection writing method using magnetization reversal by spin polarized current has been considered. In this method, the spin polarized current is applied to the MTJ element and the direction of magnetization of the storage layer is reversed. In the spin implantation method, when the volume of the storage layer, which occurs magnetization reversal, is small, the number of spin polarized electrons necessary for the reversal may be small, and thus the write current can be reduced.

### BRIEF DESCRIPTION OF THE DRAWINGS

FIG. 1 is a plan view showing a magnetic memory according to a first embodiment;

FIG. 2 is a cross-sectional view taken along line 2-2 of FIG. 1;

FIG. 3 is a cross-sectional view showing an MTJ element of the first embodiment;

FIG. 4 is a cross-sectional view showing a modification of the MTJ element of the first embodiment;

FIG. 5 is a plan view showing the magnetic memory according to a second embodiment;

FIG. 6 is a cross-sectional view for explaining a stress produced by a protective film of the MTJ element of the magnetic memory of FIG. 1;

FIG. 7 is a cross-sectional view for explaining a stress produced by an embedded film of the MTJ element of the magnetic memory of FIG. 5; and

FIG. 8 is an illustration for explaining a relationship between a distance in a radial direction from a center of the MTJ element and a stress in a thickness direction between a storage layer and a tunnel barrier layer in a case where stresses are applied to the storage layer and the tunnel barrier layer.

### DETAILED DESCRIPTION

Embodiments will be hereinafter described with reference to the accompanying drawings. Portions common to all the figures will be denoted by the common signs, and overlapping explanations will be omitted. The drawings are schematic views for promoting explanation and understanding of the embodiments, and the shapes, sizes, ratios, etc. therein may differ from those of an actual apparatus, but these can be changed in design appropriately by referring to the following descriptions and well-known techniques.

According to one of the embodiments, a magnetic memory is disclosed. The magnetic memory includes a substrate and a first magnetoresistive element provided on the substrate. A second magnetoresistive element arranged next to the first magnetoresistive element is provided on the substrate. Each of the first and second magnetoresistive elements includes a laminated body. The laminated body includes a first magnetic layer, a tunnel barrier layer and a second magnetic layer. The tunnel barrier layer is provided on the first magnetic layer, and the second magnetic layer is provided on the tunnel barrier layer. A first stress member having a tensile stress as an internal stress is provided on an area including a side face of the laminated body.

According to another embodiment, a method for manufacturing the magnetic memory is disclosed. The method includes manufacturing first and second magnetoresistive elements on a substrate. The manufacturing each of the first and second magnetoresistive elements includes forming a laminated body on the substrate. The laminated body includes a first magnetic layer, a tunnel barrier layer formed on the first magnetic layer, and a second magnetic layer formed on the tunnel barrier layer. The manufacturing each of the first and second magnetoresistive elements further includes forming a first stress member having a tensile stress as an internal stress on an area including a side face of the laminated body.

### First Embodiment

An embodiment will be described hereinafter by taking an MRAM (semiconductor memory) including an MTJ element (magnetoresistive effect element) of a spin injection writing method using a perpendicular magnetization film as an example. The perpendicular magnetization film is a magnetization film in which the direction of magnetization (direction of axis of easy magnetization) is nearly perpendicular to the film plane of the perpendicular magnetization film.

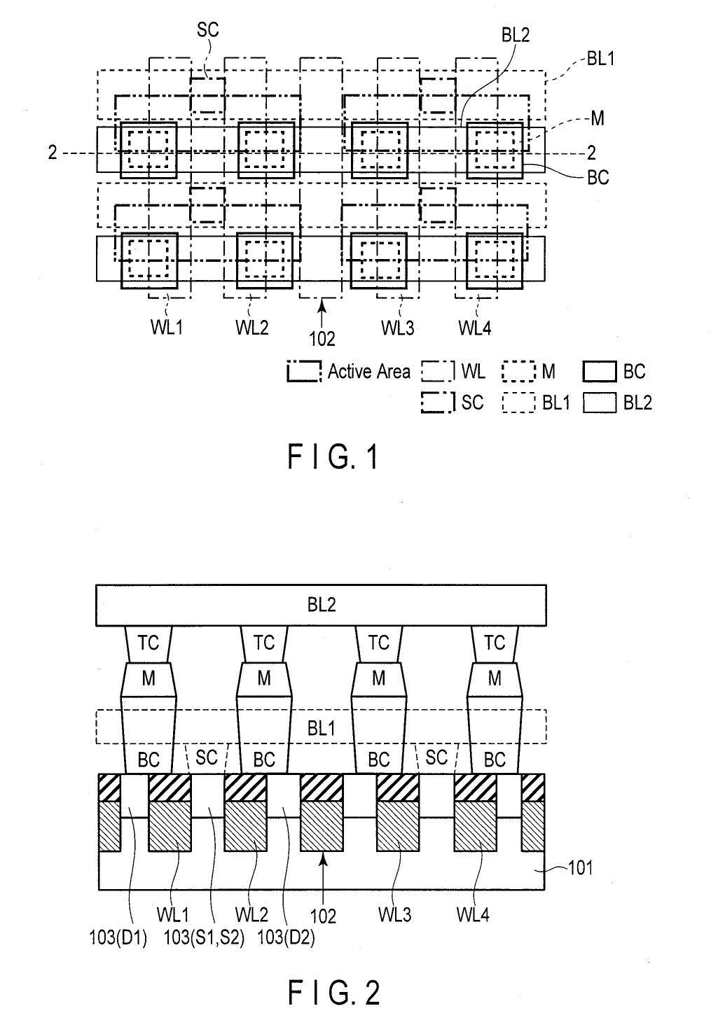

FIG. 1 is a plan view showing schematically a magnetic memory according to a first embodiment, and FIG. 2 is a cross-sectional view taken along line 2-2 of FIG. 1.

In the figures, reference numeral 101 denotes a silicon substrate (semiconductor substrate), and a dummy gate electrode 102 is formed on a surface of the silicon substrate 101. An insulating film is formed on the dummy gate electrode 102. The dummy gate electrode 102 defines active areas. In the figure, four active areas are shown.

The semiconductor substrate may not necessarily be the silicon substrate 101, and may be other substrates. Besides, a semiconductor structure or the like may be formed on these various substrates.

The MRAM of the present embodiment comprises a first selection transistor of which gate electrode is a word line WL1, a first MTJ element M connected to one of source/drain regions 103 (drain region D1) of this first selection transistor, a second selection transistor of which gate electrode is a word line WL2, and a second MTJ element M connected to one of source/drain regions 103 (drain region D2) of this second selection transistor.

That is, one memory cell of the present embodiment comprises one MTJ (memory element) and one selection transistor, the two select transistors of the two neighboring memory cells share the other source/drain region 103 (source region S1, S2).

The gate (gate insulating film, gate electrode) of the select transistor in the present embodiment is the BG as with the element isolation region 102.

One source/drain region 103 (D1) of the first select transistor is connected to a lower part of the first MTJ element M via a plug BC. An upper part of the first MTJ element M is connected to a second bit line BL2 via a plug TC.

The other source/drain region 103 (S1) of the first selection transistor is connected to a first bit line (source line) BL1 via a plug SC.

One of the source/drain region 103 (D2) of the second selection transistor is connected to a lower part of the second MTJ element M via a plug BC. An upper part of the second MTJ element M is connected to the second bit line BL2 via a plug TC.

The other source/drain region 103 (S2) of the second selection transistor is connected to the first bit line BL1 via the plug SC.

The first selection transistor, the first MTJ element M, the second selection transistor, and the second MTJ element (two memory cells) are provided in each active area. Two neighboring active areas are isolated by the isolation region (BG) 102.

The bit lines BL1 and BL2 are configured to have alternately changed heights (at every two lines). Thereby, a pitch between neighboring BL lines is relaxed to be doubled, and a parasitic capacitance between neighboring bit lines is reduced. In the figure, the bit line BL2 is higher than the bit line BL1, but, conversely, the bit line BL2 may be higher than the bit line BL1.

The word lines WL3 and WL4 correspond to the word line WL1 and WL2, respectively. Accordingly, two memory cells are constituted by a first select transistor of which gate electrode is the word line WL3, a first MTJ element M which is connected to one source/drain region 104 of the first select transistor, a second transistor of which gate electrode is a second word line WL2, and a second MTJ element M which is connected to one source/drain region 104 of the second select transistor.

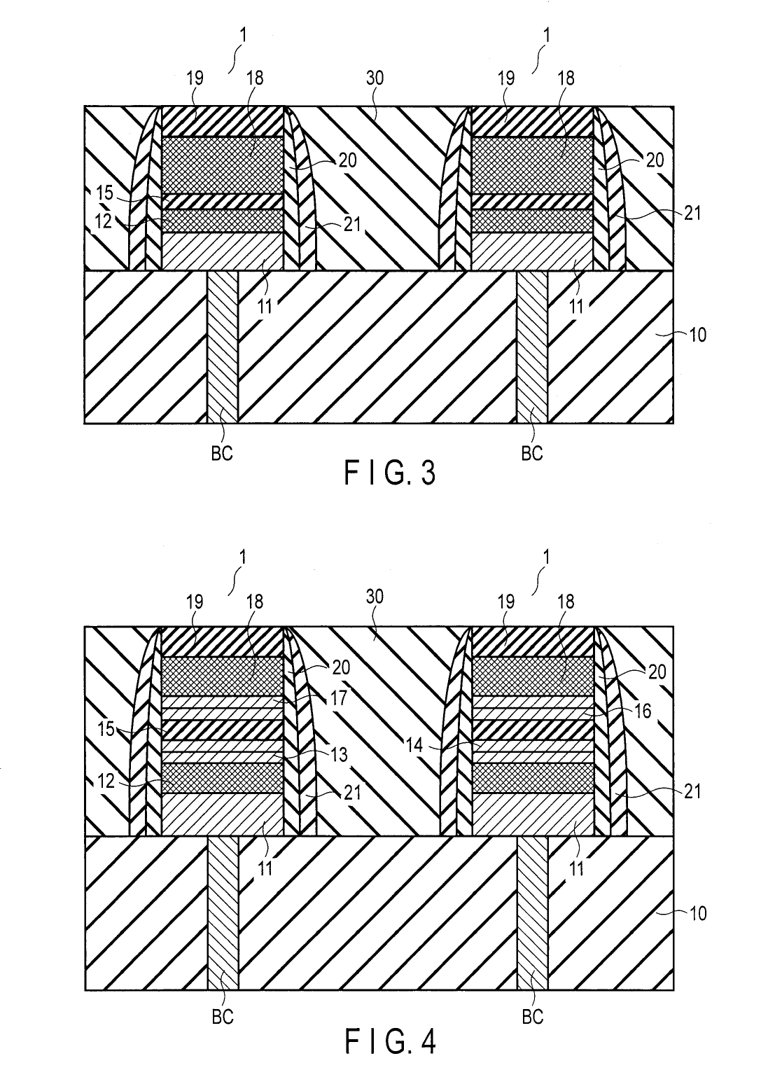

FIG. 3 is a cross-sectional view showing a concrete structure of the MTJ element of the present embodiment.

In FIG. 3, the reference numeral 10 denotes an interlayer insulating film formed on the semiconductor substrate, and a contact plug BC is formed in this interlayer insulating film 10.

The MTJ element 1 of the present embodiment has a laminated structure including a lower metal layer 11 which is formed on the interlayer insulating film 10 and is connected to the contact plug BC, a storage layer (first magnetic layer) 12 which is formed on the lower metal layer 11 and including a perpendicular magnetization film, a tunnel barrier layer (nonmagnetic layer) 15 formed on the storage layer 12, a reference layer (second magnetic layer) 18 which is formed on the tunnel barrier layer 15 and including a perpendicular magnetization film, and a cap layer 19 formed on the reference layer 18.

A shift cancelling layer may be between the reference layer 18 and the cap layer 19. The reference layer 18 is thicker than the storage layer 12, and the shift cancelling layer is thicker than the reference layer 18. The reference layer 18 and the shift cancelling layer are large layers among layers constituting the MTJ element.

The storage layer 12, the reference layer 18, or the reference layer 18 and the shift cancelling layer includes, for example, a material (Co, etc.) having a magnetostriction constant that is negative. The material having the negative magnetostriction constant includes, for example, cobalt (Co). In addition, at this time, a material having a positive magnetostriction constant, for example, a CoFeB compound, may be used for a portion which contacts the tunnel barrier layer 15.

A protective film 20 (first stress member) is formed to cover a sidewall and a top surface of the MTJ element 1. In this protective film 20, a portion covering the storage layer 12 of the protective film 20 is thicker than a portion covering the reference film 18 of the protective film 20.

This protective film 20 is, for example, such a film that has a tensile stress of several hundred megapascals or more at the inside, and that applies a force of compressing up and down along a direction of magnetization of the reference layer 18 to the MTJ element 1. This force is apt to be applied to the reference layer 18 and the shift cancelling layer, which are thick layers among the layers constituting the MTJ element 1.

In detail, although thermal stress is generated in the protective film 20 by thermal expansion coefficient difference with the MTJ element (mainly a portion comprising a metal material) at the time of temperature fall from a high film formation temperature (about 300° C.), the protective film 20 itself has the tensile stress, and thus a tensile stress from the outside of the MTJ element, which is induced in the material constituting the MTJ element, can be relaxed.

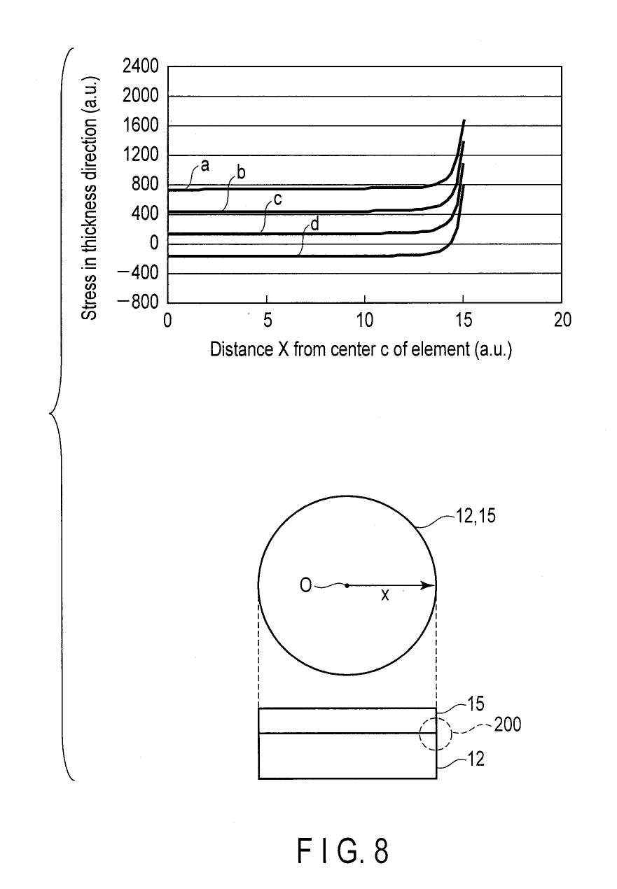

FIG. 8 is a diagram for explaining a relationship between a distance X in a radial direction from a center O of the MTJ element and a stress in a thickness direction between the storage layer 12 and the tunnel barrier layer 15 in a case where stresses a-d are applied to the storage layer 12 and the tunnel barrier layer 15. The stress in the thickness direction acts along thickness directions of the storage layer 12 and the tunnel barrier layer 15.

A magnitude relationship of the stresses (applied stresses) is a<b<c<d. In more detail, the applied stresses a and b are negative, the applied stress c is zero, and the applied stress d is positive. The applied stress d corresponds to that of the embodiment (using the protective film 20 having the tensile stress as the internal stress).

According to FIG. 8, as in the present embodiment, by using the protective film 20 having the tensile stress as the internal stress, the stress between the storage layer 112 and the tunnel barrier layer 15 can be easily made small as a whole. Thus, a stress at a portion in which the greatest stress is applied (tensile stress at an edge portion 200 of the storage layer 112 and the tunnel barrier layer 15) can be made sufficiently small. If the tensile stress between the storage layer 112 and the tunnel barrier layer 15 becomes small, a reversal current for reversing a direction of magnetization of the storage layer 112 also becomes small. Thereby, the MTJ element with low reversal current is realized, which can respond to a capacity enhancement of the MRAM in the days ahead.

The sidewall of the MTJ element 1 is covered by a sidewall film 21 having a stress via the protective film 20. The sidewall film 21 may not exist. Moreover, if the thicker of the protective film 20 and the sidewall film 21 has tensile stress as the internal stress, the other does not necessarily need to have tensile stress as the stress.

For example, if a material constituting a large portion of the MTJ element such as the reference layer 18 or the shift cancelling layer has a negative magnetostriction constant of cobalt, etc., magnetic property such as a perpendicular magnetic anisotropy deteriorate is deteriorated by applying the tensile stress to the MTJ element in a perpendicular direction. However, as in the present embodiment, by applying the internal stress to the protective film 20, the thermal stress applied to the MTJ element 1 is relaxed, application of a stress in an undesirable direction is suppressed, and deterioration of the magnetic properties is suppressed. Thereby, magnetization in a desirable direction can be stabilized.

Moreover, if a portion covering the storage layer 12 of the sidewall film 21 is made thick, the thermal stress applied to the storage layer 12 can be further relaxed. Thereby, the stability of magnetization direction stored in the storage layer 12 against thermal disturbance or the like can be improved. As a result, for example, dispersions of magnetic and electrical properties of the MTJ element 1 such as writing current, activation energy for magnetic reversal, or perpendicular magnetic anisotropy can be suppressed.

Furthermore, as shown in FIG. 4, which is a cross-sectional view of a modification of the present embodiment, interfacial magnetic films 14 and 16 may be formed between the storage layer 12 and the tunnel barrier layer 15, and between the tunnel barrier layer 15 and the reference layer 18, respectively. Moreover, diffusion prevention films 13 and 17 may be formed between the storage layer 12 and the interfacial magnetic layer 14, and between the interfacial magnetic layer 16 and the reference layer 18, respectively.

Since the interfacial magnetic films 14 and 16 have a high polarization ratio, the MTJ element 1 can achieve a larger TMR effect by having the interfacial magnetic films 14 and 16. In addition, since the diffusion prevention films 13 and 17 are provided in the MTJ element 1, a metal element constituting each layer is prevented from diffusing in heat treatment steps such as crystallization heat treatment of the tunnel barrier layer 15, formation of the insulating film 30, RIE (reactive ion etching) or interconnection formation in a manufacturing steps of the MRAM, and furthermore magnetization properties of the storage layer 12 and the reference layer 18 and electrical property (TMR effect, etc.) of the MTJ element 1 are prevented from deteriorating. In addition, since the diffusion prevention films 13 and 17 are provided, the interfacial magnetic films 14 and 16 can hold crystallinity for maintaining a large TMR effect, and similarly, the storage layer 12 and the reference layer 18 also can hold crystallinity for maintaining a sufficient perpendicular magnetic anisotropy.

It is noted that the laminated structure of the MTJ element 1 is not limited to those shown in FIG. 3 and FIG. 4, and can take various forms.

Furthermore, as shown in FIG. 3 and FIG. 4, the insulating film 30 is embedded between MTJ elements 1, and moreover, an interlayer insulating film (not shown in the figures) is provided on the MTJ elements 1 and the insulating film 30. In this interlayer insulating film, a contact plug (not shown in the figures) is provided, and this contact plug electrically connects an upper electrode layer (not shown in the figures) of the MTJ elements 1 and an interconnect on the interlayer insulating film. Moreover, the adjacent MTJ elements 1 can be electrically connected by this interconnect.

In detail, the lower metal layer 11 is formed of Pt, Ir, Ru, Cu, etc. The lower metal layer 11 may function as an orientation control film for forming the storage layer 12 on the lower metal layer 11.

As the storage layer 12, an alloy including at least one of Fe, Co and Ni and at least one of Cr, Pt, Pd, Ir, Rh, Ru, Os, Re and Au, or an artificial lattice perpendicular magnetization film in which such an alloy is laminated can be used. Specifically, for example, it is a film laminated by a combination of a magnetic material layer and a nonmagnetic material layer such as Co/Pt, Co/Pd, and Co/Ru. The magnetizing property can be adjusted by composition of a magnetic material layer, a ratio of the magnetic layer and the nonmagnetic layer, etc. In addition, the storage layer 12 can be formed by combining PtMn, IrMn, etc., which are antiferromagnetic material films, with a Ru film. Alternatively, an alloy system such as CoFeB can be used. The property of CoFeB varies according to the composition ratio of Co and Fe, and B concentrations, and thus one which fits each MTJ structure is used.

As the tunnel barrier layer 15, MgO, CaO, SrO, TiO, VO, NbO, Al₂O₃, etc., can be used; however, an oxide having an NaCl structure is desirable. For example, if crystal growth is caused on a structure of an alloy whose major component is Fe, Co, Ni, etc., for example, an amorphous CoFeB alloy, the tunnel barrier layer 15 including an insulating film preferentially oriented in (100) plane can be obtained. The thickness of the tunnel barrier layer 15 is, for example, about 10 angstroms, and its areal resistance is 10 Ωμm².

As the reference layer 18, an L10-type ordered alloy layer such as FePd, FePt is used. By adding an element such as Cu to such an ordered alloy layer, saturation magnetization and anisotropic magnetic energy density of the ordered alloy layer can be adjusted.

As the cap layer 19, a film including Ru, Ta, etc., is used.

The interfacial magnetic layers 14 and 16 must have good matching properties with the (100) plane of the tunnel barrier layer 15 including an oxide of an NaCl structure and with interfaces with the storage layer 12 and the reference layer 18, thus, as a material used for the interfacial magnetic layers 14 and 16, a material having small lattice mismatching with the (100) plane of the tunnel barrier layer 15 is preferably selected. For example, CoFeB is used as such a material. Moreover, as described above, the interfacial magnetic films 14 and 16 have a high polarization ratio, and the MTJ element 1 can achieve a greater TMR effect by having the interfacial magnetic films 14 and 16.

As the diffusion prevention films 13 and 17, a film of refractory metal such as Ti, Ta, W, Mo, Nb, Zr, Hf, or nitride or carbide of these can be used. As described above, the diffusion prevention films 13 and 17 prevent diffusion of a constituent metal element of each layer in the heat treatment steps in the manufacturing steps of the MRAM, and furthermore prevent deterioration of the magnetizing properties of the storage layer 12 and the reference layer 18 and the electrical property (TMR effect, etc.) of the MTJ element 1. In addition, the interfacial magnetic layers 14 and 16 can hold the crystallinity for maintaining the large TMR effect, and similarly, the storage layer 12 and the reference layer 18 can hold the crystallinity for maintaining the sufficient perpendicular magnetic anisotropy.

The protective film 20 preferably includes insulating material to maintain insulation between the upper electrode layer (not shown in the figures) and the lower electrode layer 11, and examples of a material having the tensile stress are silicon nitride (SiN), silicon oxynitride.

The protective film 20 can include, for example, such a SiN film formed by plasma CVD (chemical vapor deposition) (plasma nitride), which has the tensile stress of several hundred megapascals or more.

The MTJ element 1 shown in FIG. 3 and FIG. 4 is formed in the following manner.

First, after each layer constituting the laminated structure of the MTJ element 1 is formed by a well-known method, a hard mask of SiO₂, SiN or the like is formed on the laminated structure, a pattern is formed in the hard mask by using a photoresist or the like, and each layer is processed into the laminated structure of the MTJ element 1 by using the pattern. In this process, for example, a physical process by ion beam etching (IBE) or RIE is used. It is noted that as the tunnel barrier layer 15 including MgO or the like is thin and a noble metal is used, its residue adheres to the sidewall of the MTJ element 1 at the time of processing, and it may cause a leak may in the MTJ element 1, so that regarding a portion of the tunnel barrier layer 15, it is preferable to optimize a taper angle. In addition, it is preferable to optimize a processing condition, a processing gas species, post-treatment or the like so that the residue at the time of processing does not remain on the sidewall of the MTJ element 1.

Next, the protective film 20 is formed to cover the sidewall and the top surface of the MTJ element 1, or the sidewall of the MTJ element 1.

The protective film 20 is formed by using, for example, such a process as ALD (atomic layer deposition), CVD, PVD (physical vapor deposition). By forming the protective film 20 by using these processes, each layer (for example, the storage layer, the tunnel barrier layer, the reference layer) can be prevented from being damaged.

The protective film 20 is formed to prevent damage deterioration of the MTJ element 1. Specifically, damage deterioration of the MTJ element 1 by hydrogen generated at the time of forming the interlayer insulating film on the protective film 20, or damage deterioration by oxidation or the like of the MTJ element 1 caused by being exposed in an atmosphere including oxygen is prevented.

After a SiN film to be processed into the protective film 20 is deposited to cover the MTJ element 1 by using plasma CVD process, the SiN film is anisotropically etched to form the protective film 20 in which a portion covering the storage layer 12 is thicker than a portion covering the reference film 18.

Although the protective film 20 is not formed on the top surface of the MTJ element in examples of FIG. 3 and FIG. 4, the protective film 20 may be formed on the top surface of the MTJ element.

A stress state of the SiN film can be changed by changing a film formation pressure, plasma power, post-treatment or the like of the plasma CVD. By using this, the protective film 20 is formed in such a process condition as applies the tensile stress to the sidewall of the MTJ element 1.

In detail, for example, film formation is carried out by using SiH₄/NH₃/N₂ gas with low RF electrical power not higher than 0.5 to 1.0 kW, low pressure not higher than 200 kPa, and low discharge frequency of 400 kHz. In such a condition, as the ion collision increases and residual hydrogen concentrations in the SiN film change, the SiN film having the tensile stress as the internal stress can be obtained.

Alternatively, after forming the SiN film by plasma CVD process at about 300° C., the residual hydrogen concentrations in the SiN film may be reduced by irradiating the SiN film with ultraviolet rays to remove hydrogen in the SiN film. Film formation of the SiN film by the plasma CVD process is possible even at about 100° C.

Method of forming the protective film 20 is not limited to this and such method as ALD process, sputtering method, vapor deposition method also can be used. In the case of the ALD process, source gas of a silicon nitride film includes, for example, Cl-based Si gas and NH₃. The Cl-based Si gas includes dichlorosilane. The film formation temperature is, for example, about 200° C.

By the way, when miniaturization or the like of the MTJ element is advanced, magnetic anisotropic energy (energy for set a direction of magnetization in a certain direction) becomes small, and because of thermal disturbance (fluctuation in direction of magnetization of magnetic material due to thermal energy) of magnetic material, it becomes difficult to maintain stability of the directions of magnetization of the storage layer and the reference layer which the MTJ element includes. The magnetic anisotropic energy is represented by the product of a magnetic anisotropic energy density and a volume of magnetic material. To increase energy against thermal disturbance, the magnetic anisotropic energy density of the magnetization film needs to be increased.

For example, when an in-plane magnetization film having a magnetization direction in a plane of the film is used as the magnetization film of the MTJ element, a magnetic shape anisotropy is generally used to increase the magnetic anisotropic energy density. However, it is difficult to increase the magnetic anisotropic energy density by using shape magnetic anisotropy, because the reversal current is sensitive to a shape of the element, an aspect ratio of the MTJ element needs to be increased, dispersion of the shape of the element has a great influence on the property of the element in the minute MTJ element, etc. In addition, even if a material system having a large crystal anisotropy is used as the in-plane magnetization film, dispersion of magnetization in an in-plane direction becomes great and formation of the MTJ element becomes difficult.

Thus, as in the present embodiment, when the perpendicular magnetization film is used as the magnetization film of the MTJ element, a crystal magnetic anisotropy is used instead of the magnetic shape anisotropy, and thus the MTJ element can be made smaller than that of a case where the in-plane magnetization film is used. However, in general, there is a problem that the material having the crystal magnetic anisotropy (magnetization direction) in the perpendicular direction has a low polarizability and thus the magnetoresistive ratio (MR ratio) is small. On the other hand, there is a problem that the material having a high polarizability has the magnetic anisotropy in the in-plane direction and thus using the material as the perpendicular magnetization film is difficult. Also, it is conceivable to make the thickness of the magnetization film thin and thereby stabilize the direction of magnetization in the perpendicular direction by using the property of the magnetic material, but there is a problem that because each layer including the magnetization film becomes thin, an element included in each layer becomes apt to diffuse because of heat applied in the manufacturing process, and the property of the MTJ element may deteriorate.

However, in the present embodiment, since the protective film 20 applying a compression stress (having the tensile stress) along the directions of magnetization of the storage layer 12 and the reference layer 18 to the MTJ element 1 is provided, magnetization in the perpendicular direction can be stabilized. Therefore, according to the present embodiment, while the material of high MR is used, the magnetization direction can be stabilized without making the magnetization film thin. That is, the MTJ element 1 having stable property can be obtained. Moreover, according to the present embodiment, more stress is applied to the storage layer 12 by making the portion covering the storage layer 12 of the protective film 20 thicker, and hence the stability of magnetization direction stored in the storage layer 12 against thermal disturbance or the like is improved, and for example, the dispersion of the magnetic and electrical properties of the MTJ element 1 can be suppressed.

Specifically, in electrical property evaluation of the MTJ element 1 of the present embodiment, the element areal resistance (RA value) is 10 Ωμm² and the magnetoresistive ratio (MR ratio) is not less than 100%.

In the present embodiment, the MTJ element 1 with the lamination in which the storage layer 12 is upper and reference layer 18 is under is described, but is not limited to this, and the positions of the storage layer 12 and the reference layer 18 may be interchanged. In this case, a portion covering the reference layer 12 of the protective film 20 becomes thicker and more stress is applied to the reference layer 12, and hence the magnetization direction of the reference layer 12 is more stabilized, the MR ratio is prevented from deteriorating, and the thermal stability and reliability of the MTJ element 1 can be improved.

### Second Embodiment

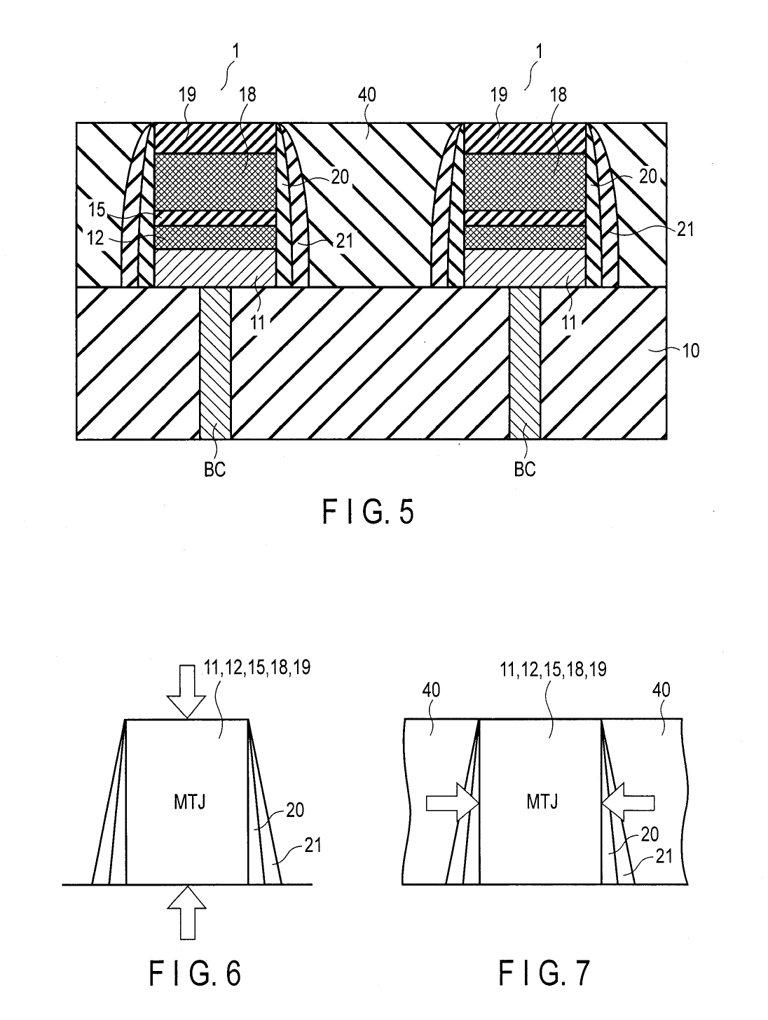

A present embodiment differs from the first embodiment in that an embedded film 40 (second stress member) which thermally expands is embedded between neighboring MTJ elements 1. The present embodiment will be described by using FIG. 5 showing a cross-section view of the magnetic memory of the present embodiment. Here, an explanation of a portion common to the first embodiment will be omitted.

As shown in FIG. 5, the MTJ elements 1 having the same laminated structure as that of the first embodiment are arranged, and the embedded film 40 is embedded between the MTJ elements 1. The embedded film 40 produces a thermal stress similarly to the protective film 20, and consequently, the embedded film 40 applies a stress to the MTJ elements 1 along directions perpendicular to directions of magnetization of the storage layer 12 and the reference layer 18 as indicated by arrows of FIG. 7. Therefore, distortion in a certain direction is applied to lattices of each magnetization film of the storage layer 12 and the reference layer 18, and the magnetization of the direction can be stabilized. When the embedded film 40 has the tensile stress as an internal stress, the stress applied to the MTJ elements is suppressed and magnetizing property of the MTJ elements are stabilized.

This embedded film 40 may be a material which thermally expands, and moreover it may be either of an insulating material and a conductive material because the MTJ elements 1 are covered by the protective film 20 and a short circuit between a lower electrode layer 11 and an upper electrode layer (not shown in the figures) is prevented.

It is noted that when the embedded film 40 is used as a self-aligned contact like a NOR-type memory, it is preferable that the embedded film 40 have at least partly the conductive material. In this case, the material having conductivity is use after an oxidation process or a nitridation process. As such a material, there are, for example, TiN, NbN, WN₂, etc.

In addition, to more surely insulate between the MTJ elements 1, it is preferable that the embedded film 40 includes the insulating material, and s a material which has insulating property after the oxidation process or the nitridation process, there are, for example, TiOx, NbO, MoOx, WOx, SiO₂, Al₂O₃, SiN, AlN or the like.

The embedded film 40 shown in FIG. 5 is formed in the following manner.

The embedded film 40 is formed by way of film formation between the MTJ elements 1 by sputtering method or vapor deposition method in a state that metal film such as Ti, Si, Mg, Al is excessively oxidized or nitrided. At this time, the oxidation may be performed by generating active oxygen by plasma. The embedded film 40 including the nitride film also can be formed in a similar manner.

Alternatively, polysilazane, SOG (spin on glass spin on glass) or polycrystalline silicon, or a mixture including these components or the like may be deposited to cover the MTJ elements 1. Thereafter, the embedded film 40 having the tensile stress as the internal stress can be formed by shrinking the deposited material with heat treatment or the like.

According to the present embodiment, since the embedded film 40 applying the compression stress to the MTJ elements 1 in the directions of magnetization of the storage layer 12 and the reference layer 18 is provided, as in the first embodiment, the distortion in a certain direction is applied to the lattices of each magnetization film of the storage layer 12 and the reference layer 18, and the magnetization of the direction can be stabilized. That is, in the second embodiment, the direction of magnetization can be more stabilized by combining the stress by the embedded film 40 and the stress by the protective film 20. Moreover, since the embedded film 40 which thermally expands is formed to be embedded between the MTJ elements 1, the MRAM can be easily formed without significantly changing the manufacturing process.

The embedded film 40 may be an interlayer insulating film having the tensile stress as the internal stress.

In the present embodiment, a sidewall film 21 may be provided, or the sidewall film 21 including a material which is free from stress may be provided. Also in the present embodiment, the positions of the storage layer 12 and the reference layer 18 may be interchanged as in the first embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetic memory comprising:
a substrate;
a first magnetoresistive element provided on the substrate; and
a second magnetoresistive element which is provided on the substrate and is arranged next to the first magnetoresistive element,
each of the first and second magnetoresistive elements comprising:
a laminated body comprising a first magnetic layer, a tunnel barrier layer and a second magnetic layer, the tunnel barrier layer being provided on the first magnetic layer, the second magnetic layer being provided on the tunnel barrier layer; and
a first stress member having a tensile stress as an internal stress provided on an area including a side face of the laminated body.

2. The magnetic memory according to claim 1, wherein the first stress member has insulating property.

3. The magnetic memory according to claim 1, wherein the protective film includes silicon nitride or silicon oxynitride.

4. The magnetic memory according to claim 1, wherein the laminated body comprises a material whose magnetostriction constant is negative.

5. The magnetic memory according to claim 4, wherein the material whose magnetostriction constant is negative includes at least one metal selected from a group comprising iron, cobalt and nickel.

6. The magnetic memory according to claim 1, wherein a width of the stress member on a side face of the first magnetic layer is greater than a width of the stress member on a side face of the second magnetic layer.

7. The magnetic memory according to claim 1, further comprising:
a second stress member which is provided between the first magnetoresistive element and the second magnetoresistive element and has a tensile stress as an internal stress, the second stress member is provided on an area including the side face of the laminated body via the first stress member.

8. The magnetic memory according to claim 7, wherein the second stress member is embedded between the first magnetoresistive effect element and the second magnetoresistive effect element.

9. The magnetic memory according to claim 1, further comprising:
a first interfacial magnetic layer provided between the first magnetic layer and the tunnel barrier layer; and
a second interfacial magnetic layer provided between the second magnetic layer and the tunnel barrier layer.

10. The magnetic memory according to claim 1, further comprising:
a first diffusion prevention film provided between the first magnetic layer and the tunnel barrier layer; and
a second diffusion prevention film provided between the second magnetic layer and the tunnel barrier layer.

11. The magnetic memory according to claim 1, wherein the first magnetic layer is a storage layer.

12. The magnetic memory according to claim 1, wherein the first stress member is further provided on a top surface of the laminated body.

13. A method for manufacturing a magnetic memory comprising:
manufacturing first and second magnetoresistive elements on a substrate,
the manufacturing each of the first and the second magnetoresistive element comprising:
forming a laminated body on the substrate, the laminated body comprising a first magnetic layer, a tunnel barrier layer formed on the first magnetic layer, and a second magnetic layer formed on the tunnel barrier layer; and
forming a first stress member having a tensile stress as an internal stress on an area including a side face of the laminated body.

14. The method according to claim 13, wherein forming the first stress member comprises forming a silicon nitride film by using plasma CVD (chemical vapor deposition) process.

15. The method according to claim 14, wherein forming the first stress member comprises reducing hydrogen included in the silicon nitride film.

16. The method according to claim 14, wherein reducing the hydrogen included in the silicon nitride film comprises irradiating the silicon nitride film with ultraviolet rays.

17. The method according to claim 14, wherein source gas of the silicon nitride film includes SiH₄, NH₃ and N₂.

18. The method according to claim 13, wherein forming the first stress member comprises forming a silicon nitride film by using ALD (atomic layer deposition) process.

19. The method according to claim 18, wherein source gas of the silicon nitride film includes Cl-based Si gas and NH₃.

20. The method according to claim 19, wherein the Cl-based Si gas includes dichlorosilane.
